(19) United States
(12) Patent Application Publication
(10) Pub. No.: US 2013/0073231 A1
(43) Pub. Date: Mar. 21, 2013

(54) IN-SITU DATA ACQUISITION SYSTEMS AND METHODS

(71) Applicants: William Stagi, Burien, WA (US); Oscar E. Morel, Seattle, WA (US); Nelson Hall, Kent, WA (US); Wen Shu, Kent, WA (US); Jun Guo, Issaquah, WA (US); James Steele, Seattle, WA (US)

(72) Inventors: William Stagi, Burien, WA (US); Oscar E. Morel, Seattle, WA (US); Nelson Hall, Kent, WA (US); Wen Shu, Kent, WA (US); Jun Guo, Issaquah, WA (US); James Steele, Seattle, WA (US)

(73) Assignee: UTILX CORPORATION, Kent, WA (US)

(21) Appl. No.: 13/460,641

(22) Filed: Apr. 30, 2012

Related U.S. Application Data
(60) Provisional application No. 61/481,071, filed on Apr. 29, 2011.

(51) Int. Cl. G06F 15/00; H05K 13/00; G01R 31/12

(52) U.S. Cl. CPC G06F 15/00; G01R 31/12; H05K 13/00
USPC 702/61; 29/825

(57) ABSTRACT

Data acquisition systems and methods for acquiring test data associated with standard insulated power cables and/or power equipment such as switchgears, transformers, electric motors, etc are disclosed. The test data may then be subsequently analyzed for defects, such as the presence of faults, discharges (e.g., PD, coronas, arcing, etc.). The systems may store the acquired test data on removable, non volatile memory, such as Flash memory. The removable memory may be retrieved by an un-skilled technician periodically and returned to a lab or other test facility for subsequent analysis by highly trained analysts.

### CROSS-REFERENCE TO RELATED APPLICATION

This application claims the benefit of U.S. Provisional Application No. 61/481,071, filed. Apr. 29, 2011, which is expressly incorporated herein by reference in its entirety.

### BACKGROUND

As electrical systems age, defects such as: cavities inside of insulating materials; thinning of insulation in motor and transformer windings; contamination across insulating surfaces; incorrect voltage to ground spacing; etc., can begin to discharge. The presence of these electrical discharges is an indicator of hidden defects which, if left unattended, can lead to system failure. In fact, the discharges themselves will, over time, degrade the material that is sustaining them also leading to system failure. Because these discharges may occur within the interior of an insulating material and because these discharge events can be very small in absolute magnitude, their presence can be unnoticeable to human senses.

In response, a variety of testing devices and methodologies have been developed to detect the presence of discharges, and to analyze those discharges using a variety of physical criteria in an attempt to identify their root cause and location. These tests require specialized testing equipment and trained personnel to acquire and analyze the data. The practical aspects; including the cost, of sending a data acquisition crew to the site limits the frequency with which the testing can be performed. Often times the testing is performed only once late in the life of the system. Other times, a regular testing schedule is adhered to, but the increments of that schedule are typically one to five years.

It is also known that changing system conditions including external conditions such as humidity and rain can change the magnitude of certain discharges temporarily. Other events, such as lighting strikes, or physical damage can dramatically change the condition of a cable instantaneously. Even intrinsic systemic conditions such as load variation, outages, power surges and switching can change the condition of a cable, or the intensity of the discharge incrementally and often intermittently. Therefore, the issues of on-site technician cost leading to sparse testing frequency is a disadvantage that needs to be overcome.

### SUMMARY

Embodiments of the present disclosure aim to resolve the challenges set forth above and others by providing methods and apparatuses which take data autonomously either by manual activation or through the use of an automated test/sleep mode schedule. In some embodiments, the apparatuses will receive its data through sensors permanently mounted to the power system. In some embodiments, the data will be processed for the purpose of minimizing the digital storage space of the system. In embodiments described herein, the data will be stored on removable media, or the data may be retrievable by equipping the device with a communication protocol for data transfer by wire or air. By automating the testing frequency, data trending can be performed without requiring multiple technician visits. Transfer of data from the device to that analyst can be performed by existing on-site personnel without any need for specialized training. By limiting the processing performed on-site by some embodiments of the present disclosure, the device can be manufactured inexpensively to provide advantageous cost/benefit when compared to on-site testing. The embodiments of the present disclosure therefore addresses the inherent disadvantages of existing systems without compromising the current need for analysis performed by highly specialized analysts.

In accordance with aspects of the present disclosure, a method is provided for acquiring one or more discharge events from a power system having a plurality of power cables supplying power to a plurality of loads. The method comprises detecting signals associated with power components of the power system with a plurality of sensors. The signals include power and one or more of noise and discharge, wherein the plurality of sensors are permanently associated with the power system. The method also includes transmitting the signals to a location separate from the power system and storing the signals as test data onto a removable computer storage media at the location.

In accordance with another aspect of the present disclosure, a data acquisition system is provided. The system includes a plurality of sensors permanently associated with a plurality of power components of a power system. The plurality of sensors are configured to sense discharge events on the associated power components. The system also includes a plurality of signal cables coupled to the plurality of sensors and routed to a location remote from the power system and a data acquisition unit stationarily mounted and coupled to the plurality of signal cables. In one embodiment, the data acquisition device is permanently mounted at the location. The unit includes one or more processors, a real time clock, non-removably computer-readable storage media having stored thereon program instructions configured to, when executed, store signals detected by at least one of the plurality of sensors and received by the data acquisition unit as test data for a selected duration of time.

In accordance with another aspect of the present disclosure, a method of installing a data acquisition system in a power system is provided. The power system includes a plurality of cables delivering power to a plurality of loads. The method includes coupling a plurality of sensors to power components of the power system. The plurality of sensors are configured to detect signals associated with power components of the power system. The method also includes routing a plurality of signal cables from the plurality of sensors to a location outside of a restriction zone of the power system, and stationarily disposing a data acquisition device at the location outside of a restriction zone of the power system and connecting the plurality of signal cables to the data acquisition device. In one embodiment, the data acquisition device is permanently mounted at the location. The data acquisition device comprises one or more processors, a removable computer storage media interface, computer-readable storage media, program instructions stored on the computer-readable storage media and configured to, when executed by the one or more processors, store signals detected by the sensors and routed to the data acquisition device on a removable computer storage media associated with the removable computer storage media interface.

This summary has been provided to introduce a selection of concepts in a simplified form that are further described below in the Detailed Description. This summary is not intended to identify key features of the claimed subject matter, nor is it intended to be used as an aid in determining the scope of the claimed subject matter.

### DESCRIPTION OF THE DRAWINGS

The foregoing aspects and many of the attendant advantages of this invention will become more readily appreciated as the same become better understood by reference to the following detailed description, when taken in conjunction with the accompanying drawings, wherein:

FIG. 1 is a schematic diagram of one embodiment of a data acquisition system associated with a power system;

FIG. 2 is a perspective view depicting a sensor formed in accordance with aspects of the present disclosure capacitively coupled to an insulated power cable;

FIG. 3 is a partial cross sectional view of a sensor integrally formed as part of a termination elbow;

FIG. 4 is a block diagram of one embodiment of a data acquisition system formed in accordance with aspects of the present disclosure;

FIG. 5 is a block diagram of another embodiment of a data acquisition system formed in accordance with aspects of the present disclosure; and

FIG. 6 is a block diagram of yet another embodiment of a data acquisition system formed in accordance with aspects of the present disclosure;

FIG. 7 is a block diagram of still yet another embodiment of a data acquisition system formed in accordance with aspects of the present disclosure; and

FIG. 8 is a block diagram of still yet another embodiment of a data acquisition system formed in accordance with aspects of the present disclosure.

### DETAILED DESCRIPTION

The detailed description set forth below in connection with the appended drawings where like numerals reference like elements is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the disclosure to the precise forms disclosed. Similarly, any steps described herein may be interchangeable with other steps, or combinations of steps, in order to achieve the same or substantially similar result.

Embodiments of the present disclosure are generally directed to data acquisition systems for acquiring test data associated with standard insulated power cables and power equipment such as switchgears, transformers, electric motors, etc, and methods therefor. The test data may then be subsequently analyzed for defects, such as the presence of faults, discharges (e.g., PD, coronas, arcing, etc.). As will be described in more detail below, several embodiments of the present disclosure store the acquired test data on removable, non volatile memory, such as Flash memory. The removable memory may be retrieved by an un-skilled technician periodically and returned to a lab or other test facility for subsequent analysis by highly trained analysts.

In the following description, numerous specific details are set forth in order to provide a thorough understanding of exemplary embodiments of the present disclosure. It will be apparent to one skilled in the art, however, that many embodiments of the present disclosure may be practiced without some or all of the specific details. In some instances, well-known process steps have not been described in detail in order not to unnecessarily obscure various aspects of the present disclosure. It will be appreciated that embodiments of the present disclosure may employ any combination of features described herein.

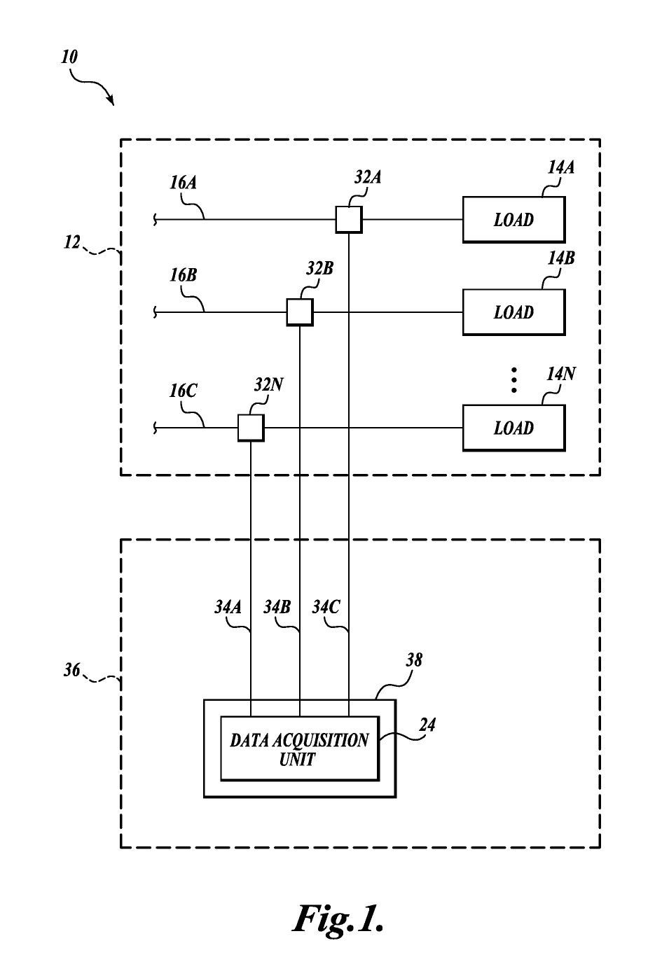

Referring now to FIG. 1, there is shown a schematic view of one example of a data acquisition system 10 formed in accordance with aspects of the present disclosure for acquiring data indicative of discharge events from a power system 12. For purposes of illustration, the power system 12 is shown as comprising a plurality of loads 14 that receive power (e.g., 60 Hz, alternating current power) via a plurality of power cables 16. In some embodiments, the power system 12 is located in a plant, substation, industrial facility, etc., and the loads 14 are in the form of power equipment, such as transformers, switchgears, electric motors, distribution blocks and/or the like.

As best shown in FIG. 1, the data acquisition system 10 comprises one or more sensors 32, shown as sensors 32A-32N, which are associated with the power cables 16 in order to detect discharge events as the loads 14 receive power from the power cables 16. It will be appreciated that the discharge events can be associated with the power cables 16 and/or with the power components associated with the loads (e.g. motors, transformers, switchgears, etc.). In some embodiments of the present disclosure, the one or more sensors 32 sense one or more signals transmitted over “live” power cables 16 carrying 50 Hz or 60 Hz frequency power. As used herein, the term “live” or “on-line” means that power is presently being transmitted along the power cable. The sensors 32A-32N are coupled to a data acquisition unit 24 via signal cables 34. The sensors 32 transmit the detected signals to the data acquisition unit 24 to be stored, and optionally displayed. The stored signals may then be retrieved by non-skilled personnel and sent to a highly skilled technician for subsequent analysis.

Referring now to FIGS. 1-4, the components of the data acquisition system 10 will be described in more detail. As briefly described above, the one or more sensors 32 monitor insulated power cables and/or their associated power equipment, such as transformers, switchgears, electric motors, etc. In one embodiment, the one or more sensors 32 sense one or more signals traveling along an on-line power cable 16 over a period a time. In any case, the one or more signals sensed by the sensors 32 (hereinafter referred to as “test signals”) may include a primary signal component attributable to power frequency, a secondary high frequency signal component attributable to faults, discharges (including both internal discharges, e.g., PD, and external discharges, e.g., coronas, arcing, etc.), or other defects caused by, for example, the power cable, power equipment coupled to the power cable, the connections between the power cable and the power equipment, etc., and tertiary signal components attributable to noise, interference, etc.

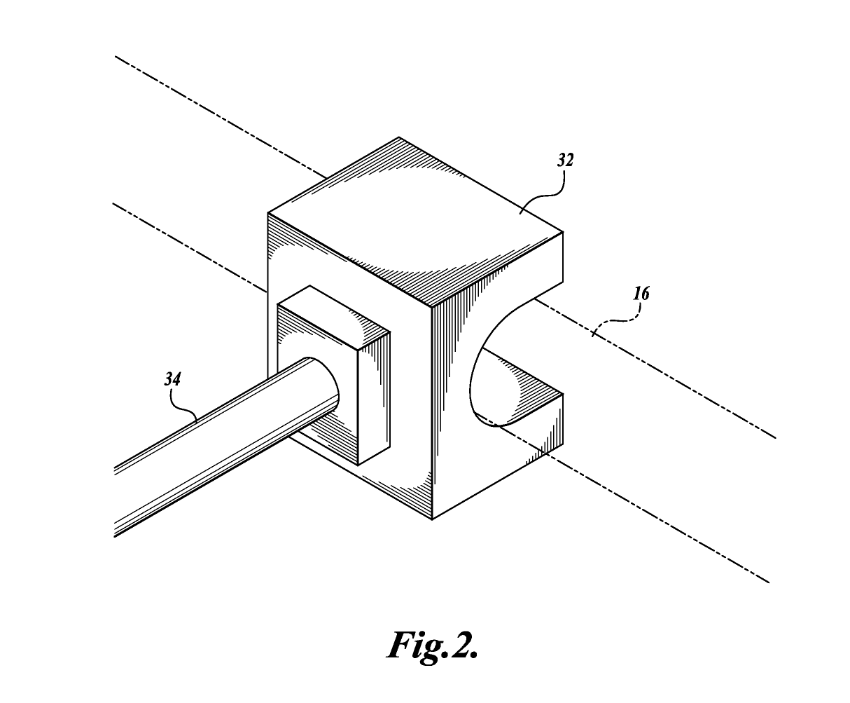

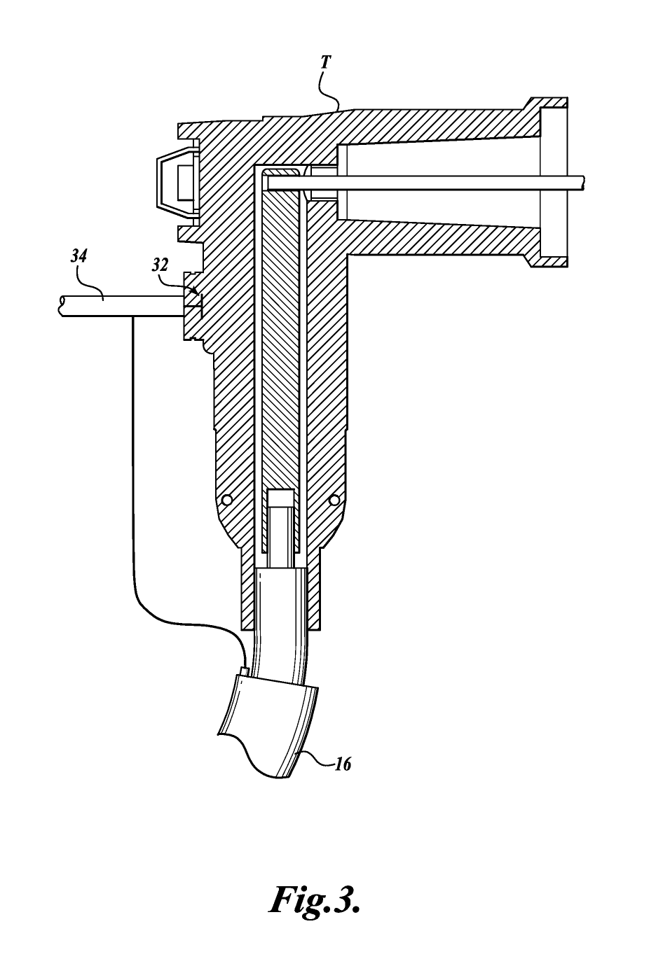

The sensors 32 may be permanently or semi-permanently positioned in the power system 12 at any suitable testing location with respect to the power components (e.g., power cables, power equipment such as transformers, switchgears, electric motors, distribution blocks, etc., and the like) of the power system to be tested. In several embodiments, the sensors 32 may be fixed in place in proximity to a termination location (e.g., power equipment, etc.), along the run of an insulated power cable such as in proximity to a cable splice, etc. The sensors 32 can be either capacitively or inductively coupled to the power components of the power system. In one embodiment, the sensors 32 each include a capacitive signal probe, such as a U-shaped metallic (e.g., copper, etc.) probe that is capacitively coupled to a respective power cable 16, as best shown in FIG. 2. In other embodiments, the sensors 32 may be a component of an electrical motor, switchgear, transformer, etc. In yet other embodiments, one or more of the sensors 32 may be a component of a termination elbow T and capacitively coupled to the insulated power cable 16, as illustrated in FIG. 3. In that regard, the sensor 32 may be formed integrally with the housing of the termination elbow T and positioned so as to be capacitively coupled to the power cable 16. Once coupled to the power components associated with the loads 14, the sensors 32 are capable of sensing the test signals associated therewith.

The sensors 32 transmit the sensed test signals to the data acquisition unit 24 via signal cables 34 for optional processing and storage, etc. The signal cables 34 can be routed from the sensors 32 to a location 36 remote from the power system 12. In some embodiments, location 36 is a location that is safe from the power system 12 and readily accessible by plant, substation, facility, etc., personnel. For example, the location 36 may be a location outside a restricted zone of the power system 12. In some embodiments, the restriction zone may be set forth by government safety requirements, such as those outlined in OSHA 29CFR 1910.269 (Occupational Safety and Health Administration for High Voltage Electrical Safety) and in the NESC (National Electrical Safety Code published by IEEE), alternatively or in addition to jobsite specific requirements or other codes addressing other non-electrical hazards especially in industrial settings.

At the location 36, the signal cables 32 terminate at the data acquisition unit 24. In some embodiments, the signal cables are routed into an access box 38, which houses the data acquisition unit 24. In these embodiments, the access box 38 is configured to withstand the somewhat harsh environment of the plant, substation, facility, etc. In some embodiments, the access box 38 can be configured with a sealable panel or lid for providing selective access to the data acquisition unit 24.

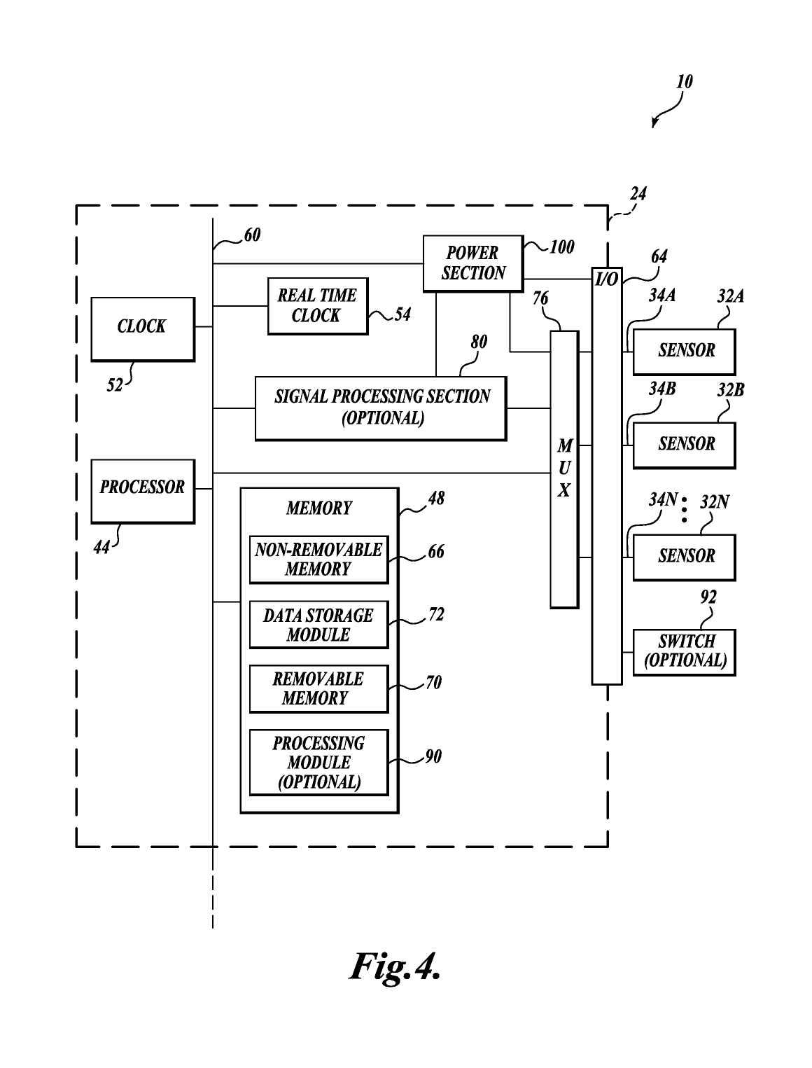

Now referring to FIG. 4, the components of one representative embodiment of the data acquisition unit 24 will be described in more detail. As best shown in FIG. 4, the data acquisition unit 24 may comprise one or more processors 44, a memory 48, a clock 52, and a real-time clock 54 suitably interconnected via one or more communication buses 60. As further depicted in FIG. 4, the data acquisition unit 24 may also include an I/O interface 64 for interfacing with, for example, the one or more sensors 32. As illustrated, the test signals sensed by the sensors 32 are received by the I/O interface 64 via signal cables 34A-34N and are transmitted to the processor 44. In the embodiment shown in FIG. 2, a multiplexer or MUX 76 is provided between the I/O interface 64 and the processor 44. In some embodiments, the MUX 76 can combine the test signals of the one or more sensors 32 and output the combined signals to the processor 44. In other embodiments, the MUX 76 can be controlled by the processor 44 to select the desired input signal from one of the sensors 32. In either case, the processor 44 receives the signals, processes the signals (optional), and stores such signals as test data in the memory 48 for subsequent analysis. It will be appreciated that the processor 44 may include indicator data to be store in conjunction with the test data. The indicator data stored with the test data associates the test data with the respective power cable from which the signals were detected. A time stamp or other similar data indicating the time and date of acquisition is also stored with the test data via techniques known in the art.

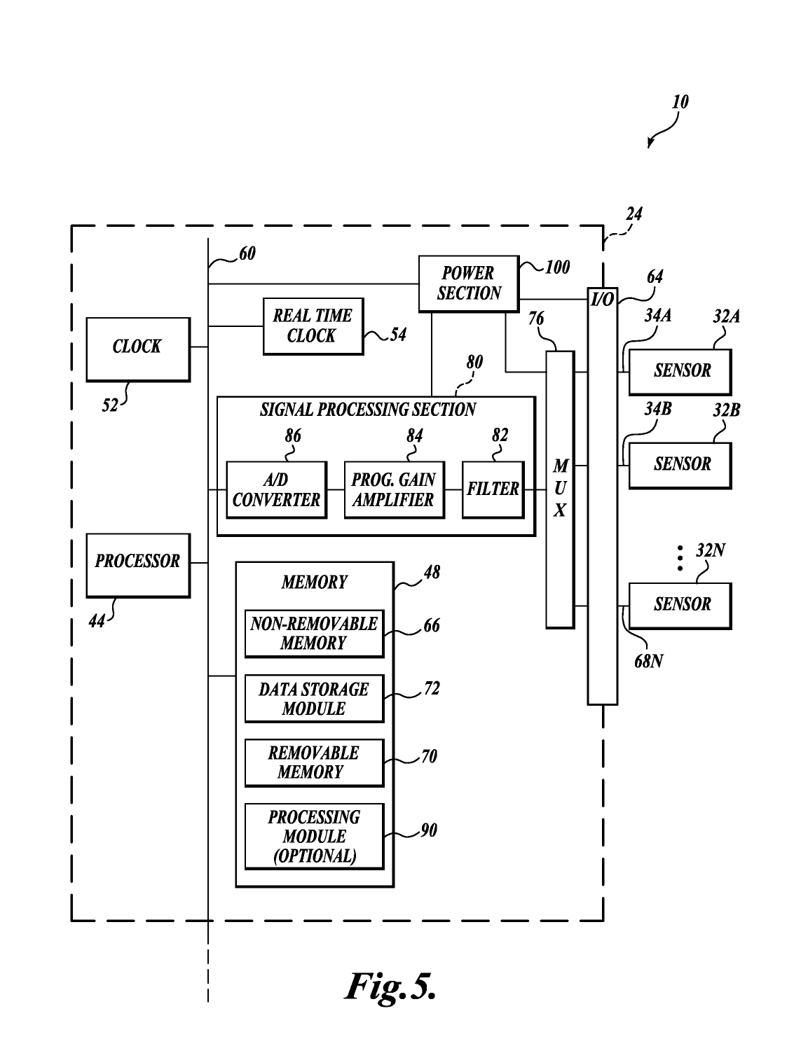

It will be appreciated that the signals outputted by the MUX 76 may be optionally processed by signal processing section 80 prior to arriving at the processor 44. For example, in one embodiment shown in FIG. 5, the signals may be conditioned by an anti-aliasing filter 82, amplified by a programmable gain amplifier 84, and analog-to-digital converted by an A/D converter 86. Other processing may occur, such as bandpass filtering to frequencies between 10 kHz and 1 GHz, for example. The A/D converter 86 in some embodiments is at least an 14 bit A/D converter having a sampling rate of 400 mega samples per second (MSPS) or greater. Other sampling rates may also be practiced with the embodiments of the present disclosure, including 20 mega samples per second (MSPS), 100 mega samples per second (MSPS) or greater. It will be further appreciated that the processing carried out by the signal processing section 80 can occur in the digital domain via digital circuitry and/or software. Also, the MUX 76 may be an analog MUX or digital MUX as known in the art.

As used herein, the term processor is not limited to integrated circuits referred to in the art as a computer, but broadly refers to any general processing device that includes but is not limited to a microcontroller, a microcomputer, a microprocessor, a programmable logic controller, an application specific integrated circuit, and other programmable circuits, among others. Those skilled in the art and others will recognize that the processor 44 serves as the computational center of the data acquisition unit 24 by supporting the execution of logic, instructions, etc., either programmed into the processor 44 or available from the memory 48. As such, the logic described herein may be implemented in hardware, in software, or a combination of hardware and software.

The memory 48 depicted in FIG. 4 is one example of computer-readable media suited to store test data and optional program modules for implementing aspects of the present disclosure. As used herein, the term “computer-readable media” includes volatile and non-volatile and removable and non-removable memory implemented in any method or technology capable of storing information, such as computer-readable instructions, data structures, program modules, or other data. The memory 48 may include read only memory (ROM), such as programmable ROM (PROM), an erasable programmable ROM (EPROM), and an electrically erasable PROM (EEPROM), etc., random access memory (RAM), and storage memory.

The storage memory provides non-volatile storage of computer readable instructions, data structures, program modules, and test data. In one embodiment, the storage memory may include a non-removable, non-volatile computer readable media in the form of a hard drive, e.g., hard disk drive, solid state drive, a Flash drive, etc. (hereafter “non-removable memory 66”), and a removable, non-volatile computer readable media in the form of flash memory (hereafter “removable memory 70”). The removable, non-volatile flash computer readable media may take the form of a device, including a USB memory stick, SD or compact flash card, or other formats known in the art. In embodiments that include the removable memory 70, the I/O circuitry 64 or separate circuitry (not shown) of the data acquisition unit 24 can be connected to the bus 60 and comprises at least one port, slot, or other removable memory interface to which the flash memory device can be operationally connected.

It will be appreciated that other removable memory 70 and their associated readers/writers may be practiced with aspects of the present disclosure. For example, the processor may effectuate storage of data onto a PCMCIA Type I or Type II memory card, a removable magnetic disk, a digital versatile disk (DVD), a BLU-ray or other high capacity digital versatile disk via its respective reader/writer device, such as a PCMCIA slot, optical disk drive, magnetic disk drive, etc. In one embodiment, the data acquisition unit includes a software module or logic that is configured to recognize the presence of the flash memory or other removable memory.

As briefly described above, the processor 44 has the responsibilities within the data acquisition unit 24 of accumulating, storing, and/or transferring the test data. Logic is provided and is executed by the processor 44 to effectuate the processing (optional) and storage of test data to either the non-removable memory 66 or the removable memory 70, or the transfer of test data from the non-removable memory 66 to the removable memory 70. In embodiments that omit the non-removable memory 66, the processor 44 effectuates the processing and storage of test data directly to the removable memory 70. It will be appreciated that the storage of data by the processor 44 may include a time stamp (date and time) from information supplied by the real time clock 54.

A number of program modules, such as application programs, may be stored in memory 48, including a data storage module 72. The data storage module 72 may be implemented automatically via instructions by the processor 44 (e.g., time based instructions), and with the assistance of the real time clock, instructs the processor 44 to store the test data at periodic intervals (e.g., every hour, every day at 12:00 pm, once a week, once a month, etc.) or on a programmed basis onto the removable memory 70. In another embodiment, the data storage module 72 may cause storage of the test data via signals received from a manually activated switch 92. In any case, the storage process may be a transfer of test data from a collection of test data stored on the non-removable memory 66, or may be the direct storage of test data received contemporaneously from one or more sensors 32 onto the removable memory 70. The data storage module 72 may also determine the time duration (e.g., 2 second, 10 seconds, one (1) minute, etc.) of collecting and storing the test data.

In some embodiments, the MUX 76 can be controlled in order to sequentially receive test signals from the sensors 32 in suitable increments for storage onto the removable memory 70. It will be appreciated that the MUX 76 may be controlled by program instructions, such as by data storage module 72, to selectively receive test signals from a subset (including a subset of one) of the sensors 32 on a periodic basis and/or selected durations. For example, the power system may include a set of power components (e.g. power cables, electric motors, transformers, etc.) that have been in service for a longer period of time as compared to other power cables and/or power components of the power system. In this case, the data storage module 72 may be configured to control the MUX 76 in order to receive test data from the sensors associated with the subset or older components at one period of time, such as once a week, etc., and receive test data from the sensors associated with the subset of the newer components at another, different time period of time, such as once a month, etc.

The memory 48 may optionally include one or more processing modules 90. The one or more processing modules 90 are configured to, when executed by the processor 44, process the test data prior to storage in memory 48. In some embodiments, processing the test data may include filtering, gain adjustment, etc. Additionally or alternatively, processing the test data alternatively or additionally may include zero span processing, Fast Fourier Transform (FFT) processing, data compression, etc.

The data acquisition unit 24 further includes a power regulation and management section 100. The power regulation and management section 100 can either receive power from one or more batteries, or may receive standard “mains” power from the associated power equipment, facility, etc. Additionally, the power section can be associated with a power source that can “harvest” parasitic power such as power derived from stray magnetic fields, temperature differentials, light, vibration, etc. The power regulation and management section 100 is configured to regulate the power supplied to the various components of the data acquisition unit 24. In some embodiments, the power regulation and management section 100 can also be configured to provide low power modes by shutting down sections of the system when not in use, and to place the system in sleep mode. This may provide energy savings, which is quite beneficial when the system is battery powered. The power regulation and management section 100 may also be configured to initiate a “wake up” event or otherwise wake the system from sleep mode using the real time clock signal so that the data acquisition unit 24 can perform the scheduled test data acquisitions. In some embodiments, these functions of the power section 100 can be incorporated into the real time clock 54.

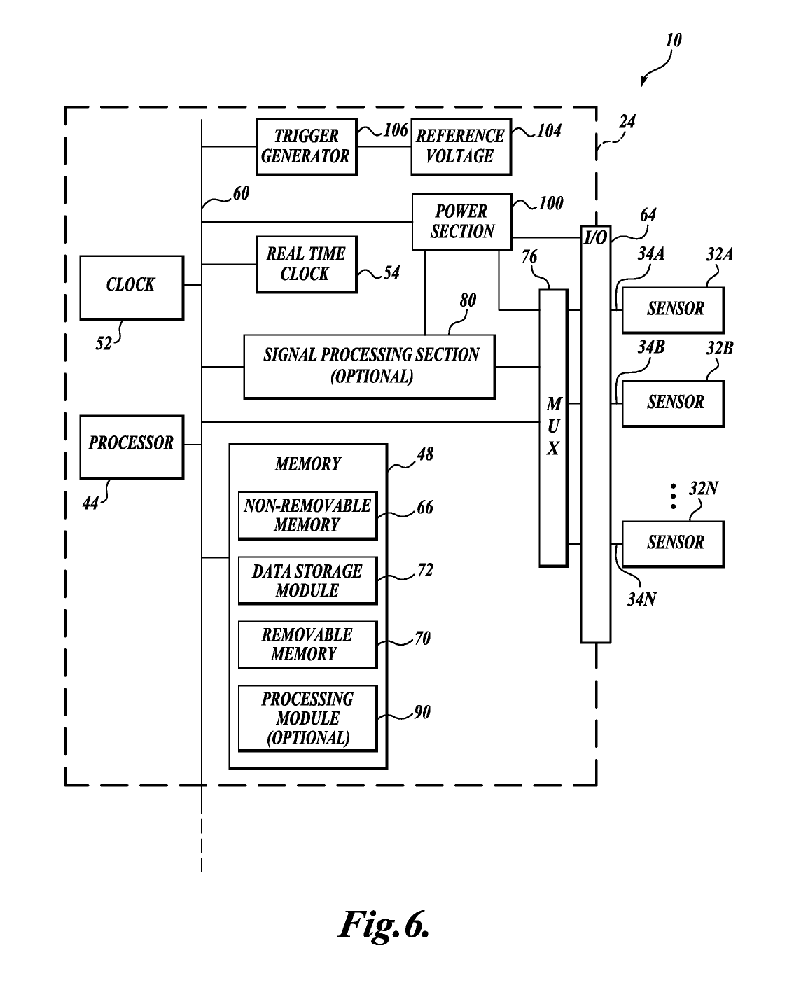

In accordance with several embodiment of the present disclosure, the processor 44 may also provide for phase reference storage of the test data. In one embodiment shown in FIG. 6, the data acquisition unit 24 may further include a reference voltage 104 and a trigger generator 106. The reference voltage 104 indicates the voltage and phase of the power carried by the power cables 14 or supplied to the power components of the power system. The trigger generator 106 receives the reference voltage from reference voltage 106 and provides a trigger to the processor 44 so that the processor 44 stores phase referenced test data in memory 48.

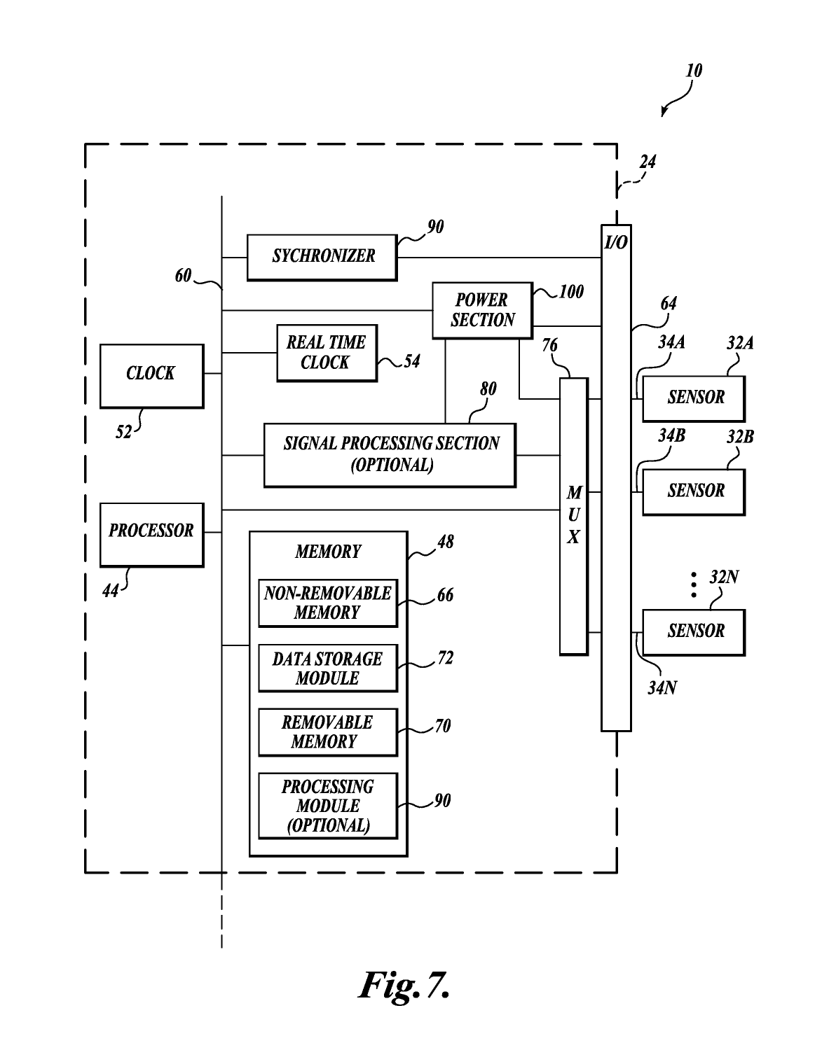

In another embodiment, the system provides for the synchronization of storage of the acquired signals to the frequency of the power transmitted over the power cables 14. To that end, embodiments of the data acquisition unit 24 as, for example, shown in FIG. 7, may optionally include a synchronizer 90 that provides information to the processor 44 that allows the test data stored by the data acquisition unit 24 to be synchronized to the frequency of the power transmitted over one of the power cables to which the sensors are coupled. In one embodiment, the synchronizer 90 provides a phase angle reference, or trigger signal, for accurate phase resolved data acquisition. Upon receipt of the trigger signal of the synchronizer 90, the processor 44 begins to store phase resolved signal data in memory 48 for future analysis. For a more detailed description of several synchronizers implemented in hardware and/or software that may be practiced with the present disclosure, please see copending U.S. application No. Ser. No. 12/605,964, filed Oct. 26, 2009, which is hereby incorporated by reference.

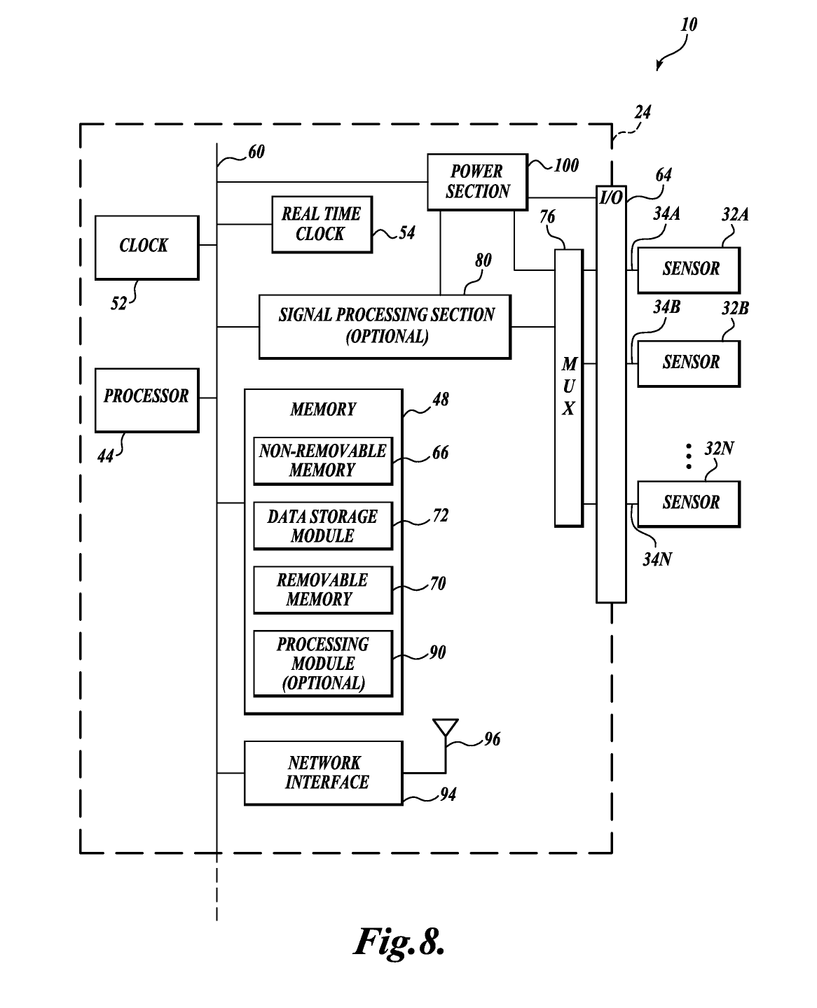

In another embodiment shown in FIG. 8, the data acquisition unit 24 may be configured to store data locally and/or transmit the data to a local and/or remote location for storage thereat. In that regard, the data acquisition unit 24 may further include a network interface 94 comprising one or more components for transmitting data via instructions from the processor 44 to local or remotes devices, such as cellular phones, PDA's, laptop computers, network terminals, general purpose computing devices, desktop computers, etc., over personal area networks (PAN), local area networks (LAN), wide area networks (WAN), such as the Internet, cellular networks, etc., using any suitable wired or wireless communication protocols. Some wired protocols that may be practiced with embodiments of the present disclosure include SCADA and IEC 61850. It should be understood that the network interface 94 may comprise components, including modems, transmitter circuitry, transmitter/receiver circuitry, or transceiver circuitry, for performing communications over the one or more networks. To communicate wirelessly, the network interface 94 may include one or more suitable antennas 96.

In one embodiment, the network interface 94 is configured to transmit test data wirelessly to a remote storage device positioned at a remote location for subsequent retrieval and analysis via instructions from the processor 44. In that regard, the network interface 94 may be configured to communicate using one or more wireless communication protocols. For example, the network interface 94 may include communication circuitry that permits wireless data transfer over one or more of the IEEE 802.11 and IEEE 802.16 networks, cellular networks, satellite networks, RF networks over the ISM band, etc. It should be understood that the network interface 94 may comprise other components, including transmitter or transmitter/receiver circuitry for performing communications using the above-identified protocols. By way of example only, these components may include but are not limited to a cellular radio or modem, satellite communication interface, RF communication interface, etc.

One method of installing a data acquisition system 10 in a power system will now be described. The power system, such as power system 12 shown in FIG. 1, may include a plurality of cables 14 delivering power to a plurality of loads 16. Generally described, trained technicians capacitively or inductively couple a plurality of sensors 32 to associated power components, such as power cables 14, of the power system 12. The sensors 32 are coupled to the power components in a permanent or semi-permanent manner so that the sensors 32 may be left in place to operate for a life span of one to three years or more. Next, signal cables 34 are connected to the plurality of sensors 32 and the signal cables 34 are routed to a separate location. In one embodiment, the location is located outside of the restriction zone, where non-trained personnel have access to. The ends of the signal cables 34 in one embodiment terminate in an access box 38. The data acquisition unit 24 is then permanently or semi-permanently mounted in the access box 38 and connected to the signal cables 34. The data acquisition unit 20 may also be connected to a low voltage source of AC power. A removable computer storage media can then coupled to the data acquisition unit 20.

Embodiments of the present disclosure provide many advantages, some of which will now be described. For example, since the data acquisition unit can be battery powered, the data acquisition unit may be installed in remote locations absent from any on-site analysts that can analyze the recorded data. And since the data acquisition unit can store the test data on removable memory, such a Flash memory, personnel who are not skilled in signal analysis can periodically retrieve the removable memory and replace the removed memory with a blank removable memory device. In this scenario, the personnel can then send the test data electronically via wireless or wired networks or physically through the mail to specialized analysts for data analysis and the like.

The data acquisition unit is also beneficial when installed at a plant, substation, industrial facility, etc., because such an installation site need not have a trained analyst on site. Rather, they can retrieve the removable storage media periodically and send the test data stored thereon to a remote testing facility for analysis.

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure.

The embodiments of the invention in which an exclusive property or privilege is claimed are defined as follows:

1. A method for acquiring one or more discharge events from a power system having a plurality of power cables supplying power to a plurality of loads, the method comprising:
detecting signals associated with power components of the power system with a plurality of sensors, the signals including power and one or more of noise and discharge, wherein the plurality of sensors are permanently associated with the power system;
transmitting the signals to a location separate from the power system;
storing the signals as test data onto a removable computer storage media at the location.

2. The method of claim 1, wherein the separate location is located outside a restriction zone of the power system.

3. The method of claim 1, further comprising
prior to storing the signals, processing the signals.

4. The method of claim 3, wherein processing comprises at least one of filtering and amplifying the signals.

5. The method of claim 3, wherein processing is selected from the group consisting of signal compression, zero span processing, and FFT processing.

6. The method of claim 1, wherein indicator data is store in conjunction with the test data, the indicator data includes data associating the test data to the respective power cable of the plurality of power cables.

7. The method of claim 6, wherein the indicator data includes time and date data.

8. The method of claim 1, wherein storing the signals as test data includes
referencing the test data to the phase of the power carried by at least one of the plurality of power cables.

9. The method of claim 1, wherein storing the test signals further includes
storing the test signals periodically according to a predetermined schedule.

10. The method of claim 9, wherein periodically includes a period of time selected from a group consisting of one hour, one day, one week, bi-monthly, monthly, and quarterly.

11. The method of claim 1, wherein storing the test signals further includes
storing test signals associated with each test sensor sequentially.

12. The method of claim 1, wherein storing the test signals further includes
storing test signals associated with each test sensor contemporaneously.

13. The method of claim 1, wherein the power components are a plurality of cables, and wherein the signals are carried by the plurality of cables, the plurality of sensors being coupled to the plurality of cables.

14. A data acquisition system, comprising:
a plurality of sensors permanently associated with a plurality of power components of a power system, the plurality of sensors configured to sense discharge events on the associated power components;
a plurality of signal cables coupled to the plurality of sensors and routed to a location remote from the power system;
a data acquisition unit stationarily mounted and coupled to the plurality of signal cables, the unit including one or more processors, a real time clock, non-removably computer-readable storage media having stored thereon program instructions configured to, when executed:
store signals detected by at least one of the plurality of sensors and received by the data acquisition unit as test data for a selected duration of time.

15. The data acquisition system of claim 14, wherein the location is located outside of a restriction zone of the power system.

16. The data acquisition system of claim 14, wherein the data acquisition unit includes a manually activated switch, and wherein the program instructions are configured to, when executed, store the test data when the switch is activated.

17. The data acquisition system of claim 14, wherein the program instructions are configured to, when executed, store the test data according to a schedule.

18. The data acquisition system of claim 17, wherein the schedule includes a period of time selected from a group consisting of one day, one week, bi-monthly, monthly, and quarterly.

19. The data acquisition system of claim 14, wherein the program instructions are configured to, when executed, store test data from a selected sensor.

20. The data acquisition system of claim 14, wherein the program instructions are configured to, when executed, receive a signal indicative of a reference phase of the power carried by at least one of the plurality of power cables and store the signals detected by at least one of the plurality of sensors and received by the data acquisition unit as phase referenced test data.

21. The data acquisition system of claim 14, further comprising
a signal processing section configured to process the signals, the processing of the signals selected from the group consisting of signal compressing, zero span processing, FFT processing, filtering, amplifying, and analog to digitally converting.

22. The data acquisition system of claim 14, further comprising removable computer-readable storage media, wherein the test data is stored on the removable computer-readable storage media

23. The data acquisition system of claim 14, further comprising
a network interface configured to transmit the test data to a remote located over a wired or wireless communication link.

24. A method of installing a data acquisition system in a power system, the power system having a plurality of cables delivering power to a plurality of loads, the method comprising:
coupling a plurality of sensors to power components of the power system, the plurality of sensors configured to detect signals associated with power components of the power system;
routing a plurality of signal cables from the plurality of sensors to a location outside of a restriction zone of the power system;
stationarily disposing a data acquisition device at the location outside of a restriction zone of the power system and connecting the plurality of signal cables to the data acquisition device, wherein the data acquisition device comprises:
one or more processors;
a removable computer storage media interface;
computer-readable storage media;
program instructions stored on the computer-readable storage media and configured to, when executed by the one or more processors, store signals detected by the sensors and routed to the data acquisition device on a removable computer storage media associated with the removable computer storage media interface.

25. The method of claim 24, further comprising
supplying power to the data acquisition device.

26. The method of claim 24, further comprising
coupling a removable computer readable storage media to the removable computer storage media interface of the data acquisition device.

27. The method of claim 24, wherein the plurality of sensors are permanently coupled to the power cables of the power system and the data acquisition device is permanently mounted at the location outside of the restriction zone of the power system.

28. The method of claim 24, wherein the data acquisition device is permanently mounted in an access box.
